(19) United States
(12) Patent Application Publication
(10) Pub. No.: US 2009/0043974 A1
(43) Pub. Date: Feb. 12, 2009

(54) SOLID-STATE IMAGING DEVICE DRIVING APPARATUS AND IMAGING APPARATUS

(75) Inventor: Shunsuke SUZUKI, Kurokawa-gun (JP)

Correspondence Address: BIRCH STEWART KOLASCH & BIRCH, PO BOX 747, FALLS CHURCH, VA, 22040-0747, US

(73) Assignee: FUJIFILM Corporation, Tokyo (JP)

(21) Appl. No.: 12/188,832

(22) Filed: Aug. 8, 2008

(30) Foreign Application Priority Data
Aug. 10, 2007 (JP) 2007-209020

(51) Int. Cl. G06F 12/00

(52) U.S. Cl. 711/154; 711/E12.001

(57) ABSTRACT

A solid-state imaging device driving apparatus for generating a driving pulse for a solid-state imaging device includes: a horizontal synchronization-related memory 50 that stores period length data being set for each of horizontal synchronization periods, and is accessed every horizontal synchronization signal; a status memory 42 that is accessed at the same timing as the horizontal synchronization-related memory 50 is accessed, and stores status data at each address as a logic value; and command data memories 42, 43, 46, and 47 that are accessed at the same timing as the horizontal synchronization-related memory 50 is accessed, and store command data sequentially. The driving pulse is generated by reading the status data from the address, which is designated by each command data, of the status memory 48.

### CROSS-REFERENCE TO RELATED APPLICATIONS

This application is based upon and claims the benefit of priority from the Japanese Patent Application No. 2007-209020 filed on Aug. 10, 2007, the entire contents of which are incorporated herein by reference.

### BACKGROUND OF THE INVENTION

1. Technical Field

The invention relates to an apparatus for driving a solid-state imaging device mounted on an imaging apparatus, such as a digital camera or the like. In particular, the invention relates to a solid-state imaging device driving apparatus and an imaging apparatus that can generate various driving pulses with a small memory capacity, to drive a solid-state imaging device.

2. Description of the Related Art

A CCD- or CMOS-type solid-state imaging device which is used in an imaging apparatus, such as a digital still camera, a digital video camera, a camera-equipped mobile phone, or the like (hereinafter, referred to as “digital camera”), is driven by driving pulses generated by an imaging device driving apparatus. For example, in the CCD-type solid-state imaging device, a vertical charge transfer path (VCCD) is driven by a vertical transfer pulse, and a horizontal charge transfer path (HCCD) is driven by a horizontal transfer pulse.

Such driving pulses are generated on the basis of data of a pulse changing point, data of a repetition number (loop number), and the like which are previously stored in a register or a memory. Many kinds of timing pulses are used for driving the solid-state imaging device. In addition, the waveforms of the pulses are complicated depending on a difference of driving modes (for example, a normal transfer mode and a high-speed transfer mode). For this reason, there arises a problem in that the amount of data in generating the driving pulses is large, and a register or a memory for storing such data must have a large capacity.

JP 2002-51270 A and JP 2001-238138 A (corresponding to 4 U.S. Pat. No. 6,873,366) disclose such a configuration that time series data representing a repetition pattern of logic levels in an output pulse is stored in a memory, and various driving pulses are generated by using the time series data.

Recently, user's request for a digital camera increases. In a digital camera, in order to increase functions and enhance its performance, driving pulses for a solid-state imaging device are complicated in period and pulse waveform, and the amount of data required for generating the driving pulses goes on increasing. JP 2002-51270 A and JP 2001-238138 A can deal with various driving pulses. When further multi modes and further multi loop stages of driving pulses are required, the memory capacity might be increased.

Furthermore, each time the design specification of a digital camera is changed to increase functions, data for generating driving pulses are inevitably changed. When pulse generation is not highly flexible, cost for designing pulse data would be increased. Recently, a digital camera that can capture images at various frame rates is attracting attention. The known design specification of a digital camera cannot deal with an arbitrary frame rate.

### SUMMARY OF THE INVENTION

The invention provides a solid-state imaging device driving apparatus and an imaging apparatus that can enable flexible design of data for generating pulses, can generate various driving pulses with a small memory capacity, and can deal with imaging at an arbitrary frame rate.

According to an aspect of the invention, a solid-state imaging device driving apparatus generates a driving pulse for a solid-state imaging device. The driving apparatus includes a horizontal synchronization-related memory, a status memory and a command data memory. The horizontal synchronization-related memory stores period length data being set for each of horizontal synchronization periods. The horizontal synchronization-related memory is accessed every horizontal synchronization signal. The status memory is accessed at the same timing as the horizontal synchronization-related memory is accessed, and stores status data at each address as a logic value. The command data memory is accessed at the same timing as the horizontal synchronization-related memory is accessed, and stores command data sequentially. The driving pulse is generated by reading the status data from the address, which is designated by each command data, of the status memory.

Also, the horizontal synchronization-related memory may store, in addition to the period length data, toggle position data of the horizontal synchronization signal being set in units of the horizontal synchronization period, toggle position data of a signal representing an image data output period, and toggle position data of a signal representing a black level output period. The respective toggle position data may be accessed every horizontal synchronization signal.

Also, the driving apparatus may further include a control section including a serial register that receives and stores plural pieces of setting data, and a sequencer section that operates with using an output of the serial register as address data and generates the driving pulses by sequence control. The control section and the sequencer section may be provided independently. The status memory, the command data memory and the horizontal synchronization-related memory may be provided in the sequencer section.

Also, the solid-state imaging device may include a CCD-type solid-state imaging device having vertical charge transfer paths and a horizontal charge transfer path. The command data memory may include a first memory section that stores command data for a plurality of horizontal synchronization periods constituting one operation period in units of the horizontal synchronization period, and a second memory section that stores command data for each horizontal synchronization period in units of a clock.

Also, the second memory section may include a clock memory that stores command data for designating different clock waiting times at different addresses, and a loop control memory that stores command data for designating number of times a clock waiting time at a designated address among the addresses is repeated.

Also, the first memory section may include a sequence memory that stores command data for designating a read address of the clock memory, and a loop pointer memory that stores commend data for, at the same timing as the command data stored in the sequence memory designates, designating a read address of the loop control memory.

Also, each of the status memory, the clock memory, and the loop control memory may be configured to be partitioned into three groups of a first group for a vertical transfer pulse, a second group for a transfer gate pulse, and a third group for a horizontal transfer pulse.

Also, when the one operation period is changed, the change of the one operation period may be dealt with by variably controlling the number of repeated loops stored in the first memory section or the second memory section.

When a same clock signal as a master clock is used as the driving pulse, the status memory may store data for designating through output of the master clock as the driving pulse in place of storing the status data of the driving pulse.

According to another aspect of the invention, an imaging apparatus includes a solid-state imaging device, and the solid-state imaging device driving apparatus for driving the solid-state imaging device.

According to the configuration set forth above, flexible design of data for generating pulses is enabled, and various driving pulse can be generated with a small memory capacity.

### BRIEF DESCRIPTION OF THE DRAWINGS

FIG. 1 is a functional block diagram illustrating main portions of a digital camera according to an embodiment of the invention.

FIG. 2 is a diagram illustrating the configuration of main portions of a solid-state imaging device shown in FIG. 1.

FIG. 3 is a detailed diagram of a timing generator shown in FIG. 1.

FIGS. 4A to 4C are diagrams illustrating the operation of the timing generator shown in FIG. 3.

FIGS. 5A and 5B are a timing chart of driving pulses illustrating a relationship between a sequence memory and a loop pointer memory shown in FIG. 4A.

FIGS. 6A and 6B are an enlarged timing chart of Pattern 1 shown in FIG. 5 illustrating a relationship between a clock memory and a loop control memory shown in FIG. 4A.

FIGS. 7A and 7B are a timing chart of driving pulses, which is the same as that shown in FIG. 6B, illustrating the relationship between the clock memory and a status memory shown in FIG. 4A.

FIG. 8 is a timing chart when a digital camera of this embodiment captures a still image.

FIG. 9 is a timing chart of a blanking period and a horizontal transfer period of a horizontal charge transfer path.

### DETAILED DESCRIPTION OF EMBODIMENTS OF THE INVENTION

Embodiments of the invention will be described with reference to the accompanying drawings.

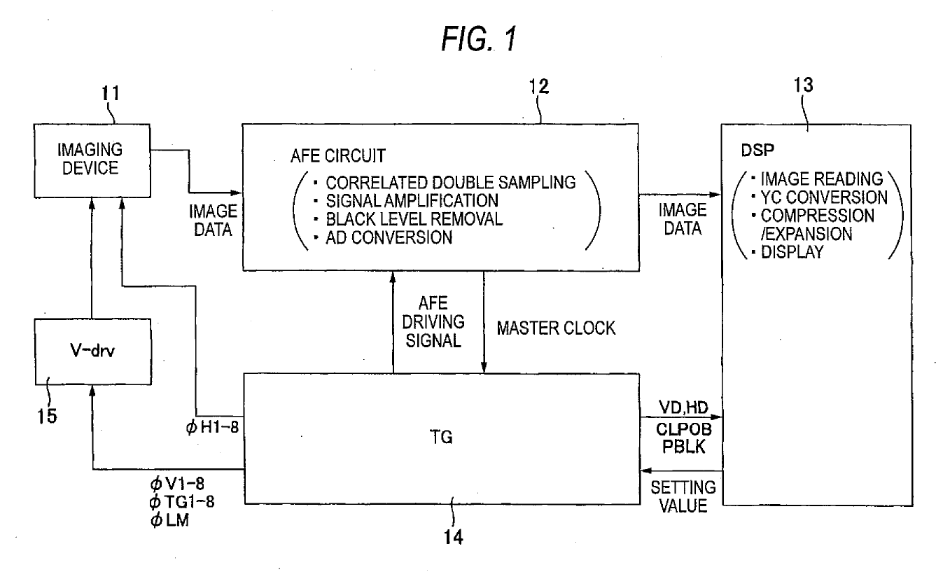

FIG. 1 is a functional block diagram illustrating main portions of a digital camera according to an embodiment of the invention. The illustrated digital camera includes a CCD-type solid-state imaging device 11, an analog front end (AFE) circuit 12 that receives analog image data output from the solid-state imaging device 11 and performs correlated double sampling, signal amplification, black level removal, analog-to-digital (AD) conversion and the like, a digital signal processor (DSP) 13 that receives digital image data output from the AFE circuit 12 and performs YC conversion, compression/expansion and the like, a timing generator (TG: driving pulse generating circuit) 14 that will be described below in detail, and a driving circuit (V-drv) 15.

The timing generator 14 operates in accordance with a master clock signal supplied from the AFE circuit 12 and setting value data supplied from the DSP 13. The timing generator 14 generates a horizontal synchronization signal HD, a vertical synchronization signal VD, a PBLK (pre-blank) signal that represents an image data output period (a period in which data is output from an effective pixel region of the solid-state imaging device and an optical black portion of the solid-state imaging device), a CLPOB (clamp optical black) signal that represents a reference black level period (a period in which data is output from the optical black portion provided around the effective pixel region), an electronic shutter (OFD) signal, horizontal transfer pulses H1 to H8, vertical transfer pulses V1 to V8, transfer gate signals (read pulse signals) TG1 to TG8, and a line memory driving pulse LM. The timing generator 14 further generates an AFE driving signal for driving the AFE circuit 12.

The horizontal synchronization signal HD, the vertical synchronization signal VD, the PBLK signal, and the CLPOB signal are supplied from the timing generator 14 to the DSP 13. The horizontal transfer pulses Hi to H8 have a voltage as low as approximately 3 V, and therefore are directly supplied to the solid-state imaging device 11. Voltages of the vertical transfer pulses V1 to V8, the transfer gate pulses TG1 to TG8, and the line memory driving pulse LM are increased in the driving circuit 15, and then supplied to the solid-state imaging device 11.

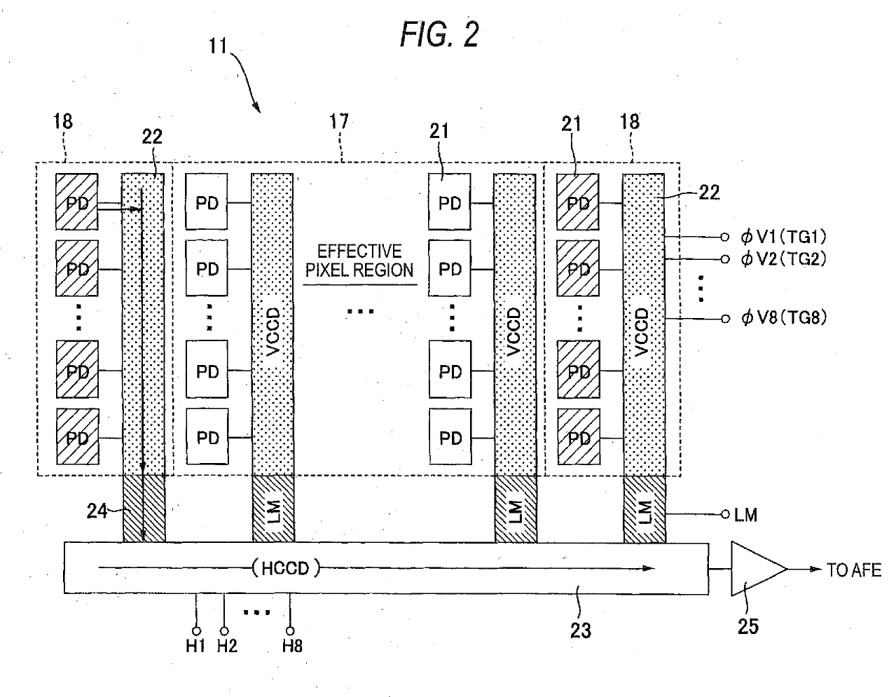

FIG. 2 is an explanatory view of the solid-state imaging device 11 shown in FIG. 1. The solid-state imaging device 11 includes a plurality of photodiodes (PDs) 21 that are arranged on a semiconductor substrate in the form of two-dimensional array, vertical charge transfer paths (VCCD) 22 that are formed along the respective photodiode columns, a horizontal charge transfer path (HCCD) 23 that is provided in a lower side portion of the semiconductor substrate, line memories (LMs) 24 that are provided between the ends of the vertical charge transfer paths 22 and the horizontal charge transfer path 23, respectively, and an output amplifier 25 that is provided at an output end of the horizontal charge transfer path 23.

In the solid-state imaging device 11, the optical black (OB) portions 18 are provided around the effective pixel region 17 being provided in a central portion of a light receiving surface (in the illustrated example, the OB portions 18 are provided only on the left and right sides). Incident surfaces of the photodiodes 21 in the optical black (OB) portions 18 are covered with a light-shielding film (in the drawing, hatched portions). Detection signals of the photodiodes in the OB portions 18 serve as black level reference signals.

As disclosed in, for example, JP 2000-350099 A (corresponding to U.S. Pat. No. 6,885,399), each of the line memories 24 temporarily stores signal charges transferred by the corresponding vertical charge transfer path 23, and outputs the stored charges to the horizontal charge transfer path 23 according to the line memory driving pulse LM. By controlling its output timing, it is possible to add signal charges of pixels in the horizontal direction.

In the solid-state imaging device 11 having the above configuration, when the transfer gate pulses TG1 to TG8 are applied to electrodes which serve as transfer gate electrodes, of virtual transfer electrodes constituting the vertical charge transfer paths 22, signal charges of corresponding photodiodes 21 are read into potential packets which are formed below the electrodes. Then, the vertical transfer pulses φV1 to φV8 are applied to the vertical charge transfer paths 22, thereby transferring the signal charges in the vertical charge transfer paths 22 toward the horizontal charge transfer path 23. The signal charges in the ends of the vertical charge transfer paths 22 are transferred to and temporarily held in the line memories 24.

The signal charges in the line memories 24 are transferred to the horizontal charge transfer path 23 according to the line memory driving pulse φLM. The signal charges transferred onto the horizontal charge transfer path 23 are transferred toward the output amplifier 25 according to the horizontal transfer pulses φH1 to φH8. The output amplifier 25 supplies, to the AFE circuit 12, a voltage value signal corresponding to the charge amount of each of the signal charges, which are sequentially transferred to the output end of the horizontal charge transfer path 23, as image data.

Signal charges of one lateral row in the vertical charge transfer paths 22 are transferred toward the horizontal charge transfer path 23 by one stage according to the vertical transfer pulses φV1 to φV8, and signal charges of one lateral row are transferred from the line memories 24 to the horizontal charge transfer path 23. The signal charges of this one lateral row are transferred in the horizontal direction and output from the output amplifier 25. Thereafter, signal charges in the vertical charge transfer paths 22 are transferred by another one stage toward the horizontal charge transfer path 23. These operations are repeatedly performed.

The DSP 13 shown in FIG. 1 receives the output signal from the output amplifier 25, and performs image processing to generate captured image data of a subject. At this time, signals output from the effective pixel region 17 shown in FIG. 2 become the captured image data of the subject, and signals output from the OB portions 18 become data for determining the black level.

Output signals of one lateral photodiode row shown in FIG. 2 are output during one horizontal synchronization signal HD. When a length of a period of one horizontal synchronization signal HD is variably controlled, if the DSP 13 does not know which part of the period of the one horizontal synchronization signal HD includes output signals from the effective pixel region 17 and which part of the period of the one horizontal synchronization signal HD includes output signals from the OB portions 18, an appropriate image processing might not be performed. Accordingly, the timing generator 14 of this embodiment is configured to supply to the DSP 13 the PBLK signal and the CLPOB signal, which are described above.

The terms “vertical” and “horizonital” used herein mean “one direction” and “a direction substantially perpendicular to the one direction” along the light-receiving surface of the solid-state imaging device.

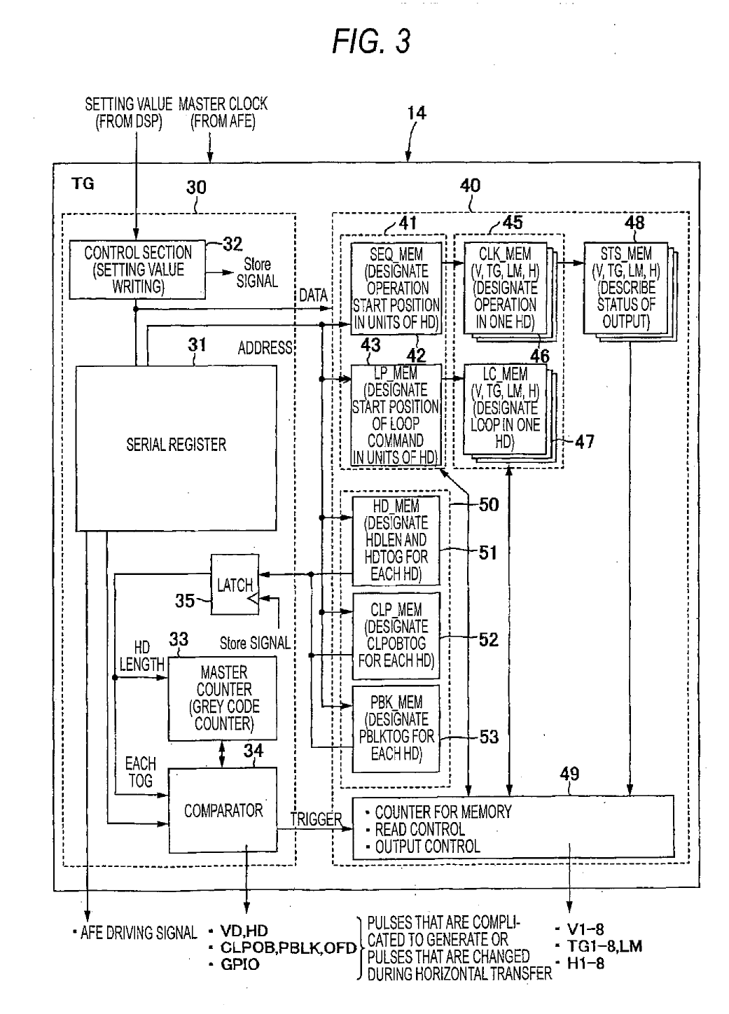

FIG. 3 is a detailed diagram of the timing generator (TG) 14 shown in FIG. 1. The timing generator 14 includes a control section & a trigger pulse generating section (hereinafter, referred to as “control/trigger pulse generating section”) 30, and a sequencer section 40 according to this embodiment.

The number of registers can be reduced by providing the sequencer section 40 and the control/trigger pulse generating section 30 independently. Also, the use performance can be improved. This is because of the following reasons. In place of generating pulses by setting registers of the control/trigger pulse generating section, this embodiment generates pulses by the sequencer section as described below. Accordingly, setting registers can be reduced. Furthermore, the pulse generation by means of sequence is more effective than the pulse generation by means of registers. Moreover, data size can be reduced.

The control/trigger pulse generating section 30 receives the setting value data (including data used to generate an AFE driving control signal and the driving pulses φH1 to φH8, TG1 to TG8, φLM, and φV1 to φV8, period data of the horizontal synchronization signal HD, and the like) from the DSP 13 as serial data. Then, the control/trigger pulse generating section 30 outputs the AFE driving control signal, the generated horizontal synchronization signal HD, the generated vertical synchronization signal VD, the generated PBLK signal representing the image data output period, the generated CLPOB signal representing the reference black level period, the generated electronic shutter (OFD) signal, and the like.

As described later in detail, the sequencer section 40 generates and outputs the horizontal transfer pulses φH1 to φH8, the vertical transfer pulses φV1 to φV8, the transfer gate pulses TG1 to TG8, and the line memory driving pulse φLM.

Also, as described later in detail, the sequencer section 40 outputs the setting value data stored in internal memories 51, 52, and 53, to the control/trigger pulse generating section 30. The setting value data stored in the internal memories 51, 52, and 53 include period length data for each horizontal synchronization signal HD, toggle position data representing a pulse edge position of each horizontal synchronization signal HD, toggle position data of the CLPOB signal for each horizontal synchronization signal HD, and toggle position data of the PBLK signal for each horizontal synchronization signal HD.

The control/trigger pulse generating section 30 includes a serial register 31 into which the setting value data supplied from the DSP 13 is written, a control section 32 that controls writing operations into the serial register 31 and the memories 42, 43, 46, 47, 48, 51, 52, and 53 (described below) of the sequencer section 40, a master counter 33 including a gray code counter, a comparator 34, and a register unit 35.

The register unit 35 operates in accordance with a store command output from the control section 32, latches the period length data (hereinafter, may be referred to as “HD length”) of the horizontal synchronization signal HD read out from the memory 51, and outputs the latched period length data to the master counter 33. Also, the register unit 35 latches the toggle position data of the horizontal synchronization signal HD, the toggle position data of the CLPOB signal, and the toggle position data of the PBLK signal, which are read out from the memories 51, 52, and 53, and outputs the respective latched toggle position data to the comparator 34.

Of the data written into the serial register 31, the comparator 34 compares data related to the horizontal synchronization signal HD and the vertical synchronization signal VD with an output value of the master counter 33, to output the horizontal synchronization signal HD and the vertical synchronization signal VD to the DSP 13, and outputs a trigger signal to the sequencer section 40.

Also, the comparator 34 compares the HD length counted by the master counter 33 with the respective toggle position data, and outputs the toggle position data of the CLPOB signal conforming to the HD value, the toggle position data of the PBLK signal conforming to the HD value, the OFD signal, and others to the DSP 13.

The serial register 31 outputs the data for driving pulse generation to the sequencer section 40 as address data.

The sequencer section 40 includes a first memory section 41, a second memory section 45, a status memory (STS_MEM) 48, an output control section 49, and an HD related memory section 50.

The first memory section 41 includes a sequence memory (SEQ_MEM) 42 and a loop pointer memory (LP_MEM) 43. In response to the same address signal supplied from the control/trigger pulse generating section 30, command data at the same address are read out from the memories 42 and 43 at the same timing.

The sequence memory 42 stores command data for designating an operation start position in units of the horizontal synchronization signals HD. The loop pointer memory 43 stores command data for designating a start position of a loop command in units of the horizontal synchronization signals RD.

The second memory section 45 includes a clock memory (CLK_MEM) 46 and a loop control memory (LC_MEM) 47. Each of the memories 46 and 47 is configured to be partitioned into three groups, that is, a group for “vertical transfer pulse”, a group for “gate transfer pulse and line memory driving pulse”, and a group for “horizontal transfer pulse”. The designer may arbitrarily set how each memory is partitioned. In this embodiment, the three-group configuration provides the most efficiently partitioning of the memories.

The clock memory 46 stores command data for designating an operation (operations) in one horizontal synchronization period HD. The command data is read out from the clock memory 46 with an output of the sequence memory 42 being used as a read address, and is then output.

The loop control memory 47 stores command data for designating a loop (loops) in one horizontal synchronization period HD. The command data is read out from the loop control memory 47 with an output of the loop pointer memory 43 being used as a read address, and the read-out command designates a read address for executing a loop in the clock memory 46.

The status memory (STS_MEM) 48 describes output statuses of the driving pulses as data. The status data is output to the output control section 49 with an output of the second memory section 45 being used as a read address.

In response to the trigger signal output from the comparator 34 of the control/trigger pulse generating section 30, the output control section 49 operates to control the first and second memory sections 41 and 45, and to output the status data supplied from the status memory 48 as the driving pulses φV1 to φV8, TG1 to TG8, φLM, and φH1 to φH8. Under a certain condition described below, the master clock signal supplied from the AFE circuit 12 to the timing generator 14 is output as the driving pulse as it is.

The command data and the status data which are to be stored in the memories 42, 43, 46, 47, and 48 are output from the DSP 13, are supplied from the control section 32 to the sequencer section 40, and are stored in the memories.

The HD-related memory section 50 includes an HD_MEM (horizontal synchronization memory) 51, a CLP_MEM (black level memory) 52, and a PBK_MEM (data output memory) 53.

The HD_MEM 51 stores the HD length, which is given as setting data, for each horizontal synchronization signal HD, and the toggle position data of each horizontal synchronization signal HD. When the designer wants to adjust the HD length to operate the solid-state imaging device, the HD lengths and the toggle positions which are stored in the memory 51 may be arbitrarily set.

When the HD length is variably controlled, as described with reference to FIG. 2, the toggle position of the PBLK signal representing the image data output period in the HD length (image data including black levels (OB portions) is output during an active period of the PBLK signal) and the toggle position of the CLPOB signal (a signal output during an active period of the CLPOB signal becomes a reference black level) are also changed.

Accordingly, for each HD length being designated for the corresponding horizontal synchronization signal HD, the corresponding toggle position data of the CLPOB signal is stored in the memory 52. Also, for each HD length being designated for the corresponding horizontal synchronization signal HD, the corresponding toggle position data of the PBLK signal is stored in the memory 53.

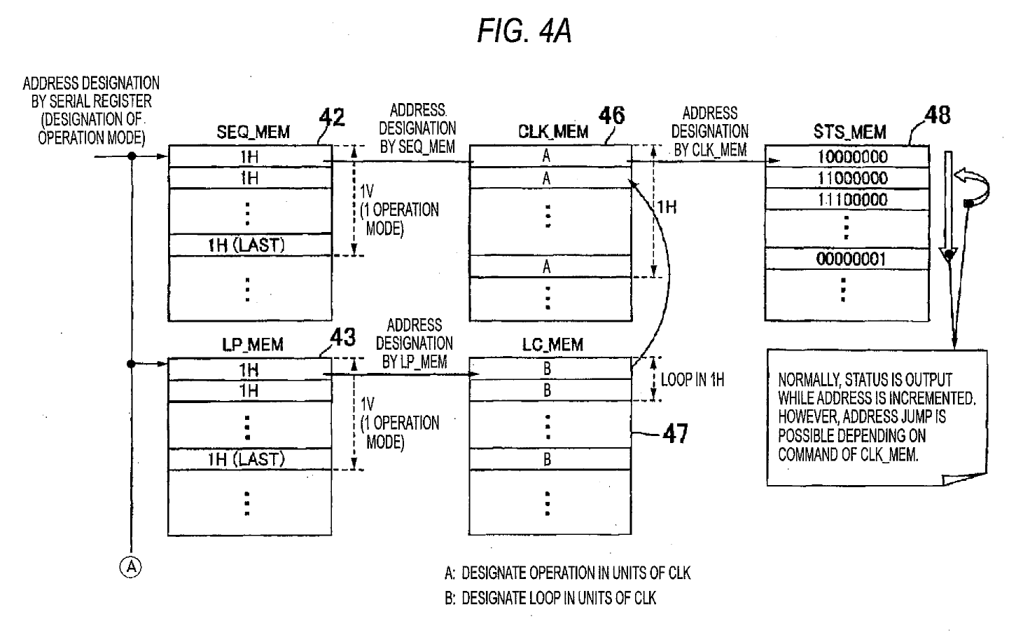

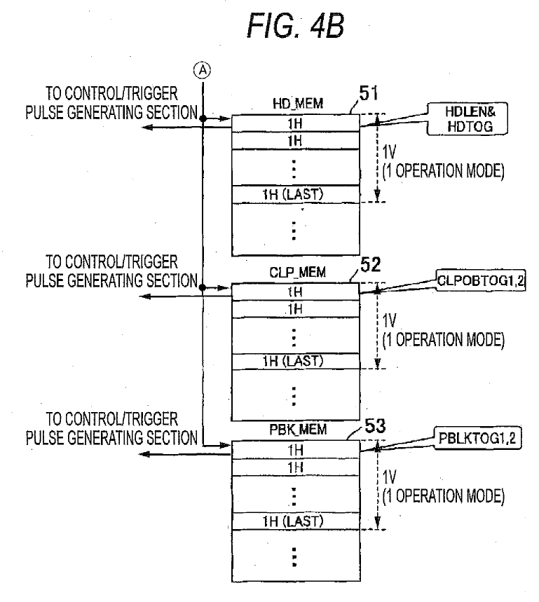

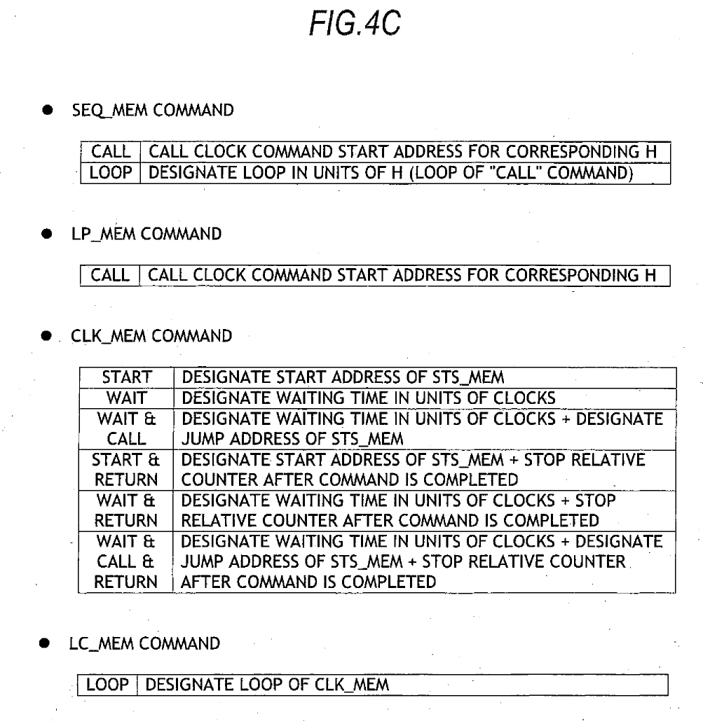

FIGS. 4A to 4C are diagrams illustrating the operation of the sequencer section 40. In the drawing, “1H” represents an area where data or command in the period of the corresponding one horizontal synchronization signal HD is stored, and “1V” represents a period of plural horizontal synchronization signals HD corresponding to a period of one vertical synchronization signal VD.

The command data to be stored in the sequence memory 42 are, for example, a call command and a loop command. The call command is a command for calling a clock command start address in a corresponding horizontal synchronization period (in a period of a corresponding horizontal synchronization signal HD) The loop command is a command for designating a loop (a loop of the call command) in units of horizontal synchronization periods.

The command data to be stored in the loop pointer memory 43 is, for example, a call command. The call command is a command for calling a loop command start address in a corresponding horizontal synchronization period.

An address of the sequence memory 42 and an address of the loop pointer memory 43 are designated by data output from the serial register 31. An address of the clock memory 46 is designated by data read out from the sequence memory 42. An address of the loop control memory 47 is designated by data read out from the loop pointer memory 43.

The command data to be stored in the clock memory 46 are, for example, a start command, a wait command, and a wait & call command. The start command is a command for designating a start address of the status memory 48. The wait command is a command for designating a waiting time in units of clocks. The wait & call command is a command for designating a waiting time in units of clocks and designating a jump address of the status memory 48.

The command data to be stored in the loop control memory 47 is, for example, a loop command. The loop command is a command for designating a loop in the clock memory 46 in units of clocks.

The status memory 48 stores statuses in the form of a binary logic value, and outputs a status at the designated address which is read out from the clock memory 46. The driving pulses are generated based on a change in the status read out from the status memory 48. Normally, the read address of the status memory 48 is incremented one by one. However, address jumping may be sometimes caused by a command of the clock memory 46.

The HD memory 51 stores the HD length and the toggle position data for every one horizontal synchronization signal HD. The CLP memory 52 stores the toggle position data of the CLPOB signal for every one horizontal synchronization signal HD. The PBK memory 53 stores the toggle position data of the PBLK signal for every one horizontal synchronization signal HD. The memories 51, 52, and 53 are accessed at the same timing as the sequence memory 42 and the loop pointer memory 43, every horizontal synchronization signal HD. Then, the HD length data, the HD toggle position data, the CLPOB toggle position data, and the PBLK toggle position data are read out and output to the control/trigger pulse generating section 30.

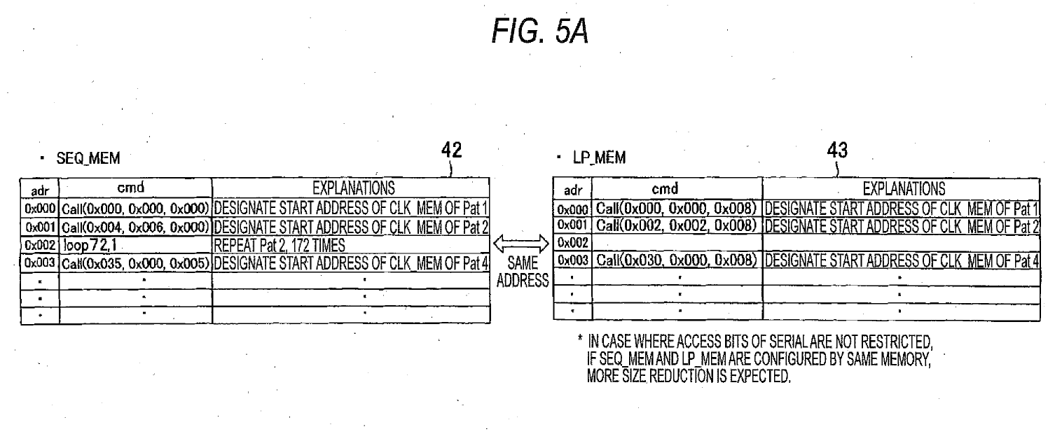

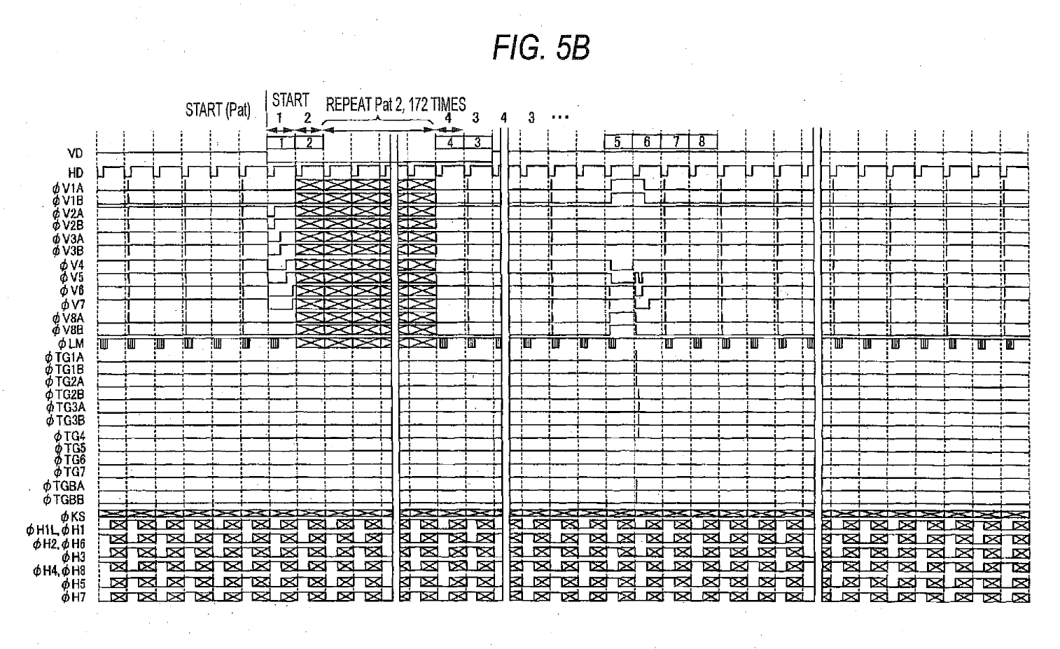

FIGS. 5A and 5B are a timing chart of the driving pulses. This timing chart shows high-speed sweep driving, which is performed before signals are output from the CCD-type solid-state imaging device, and reading-out of signal charges from the photodiodes to the vertical charge transfer paths, which is executed subsequent to the sweep driving Upon start, first, the driving of the vertical charge transfer paths is started with the waveforms of Pattern (Pat) 1, and then the sweep driving is performed by repeating 172 times Pattern 2 of high-speed pulse waveforms. Thereafter, Pattern 4, Pattern 3, Pattern 4, Pattern 3, . . . are repeated, and then driving of Pattern 5 is performed, to thereby perform idle transfer on the vertical charge transfer paths. In Pattern 6, the transfer gate pulse signals are applied to read out the signal charges from the corresponding photodiodes to the vertical charge transfer paths. Thereafter, the process proceeds to Patterns 7, 8, . . . .

The control of each of Patterns 1, 2, . . . is performed in units of horizontal synchronization periods. A HD length of each horizontal synchronization period HD is controlled so as to be the HD length read out from the HD memory 51.

In order to allow the sequencer section 40 to generate the driving pulses of Patterns 1, 2, . . . shown in FIG. 5, in this embodiment, a command for designating a clock memory start address of Pattern 1 is stored at an address “0X000” of the sequence memory 42, as shown in FIG. 5A. At the next address “0x001”, a command for designating a clock memory start address of Pattern 2 is stored. At the next address “0x002”, a command for designating the operation to repeat Pattern 2 172 times is stored. At the next address “0x003”, a command for designating a clock memory start address of Pattern 4 is stored.

Also, in the loop pointer memory 43, address designation is performed in the same manner as in the sequence memory 42. As shown in FIG. 5A, a command for designating a loop control memory start address of Pattern 1 is stored at an address “0x000”. At the next address “0x001”, a command for designating a loop control memory start address of Pattern 2 is stored. At the next address “0x002”, no operation (a command for performing nothing) is stored. At the next address “0x003”, a command for designating a loop control memory start address of Pattern 4 is stored.

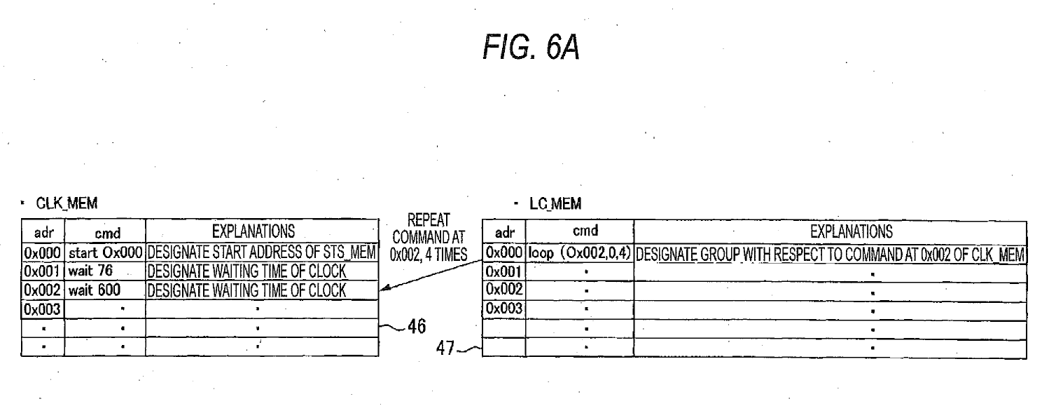

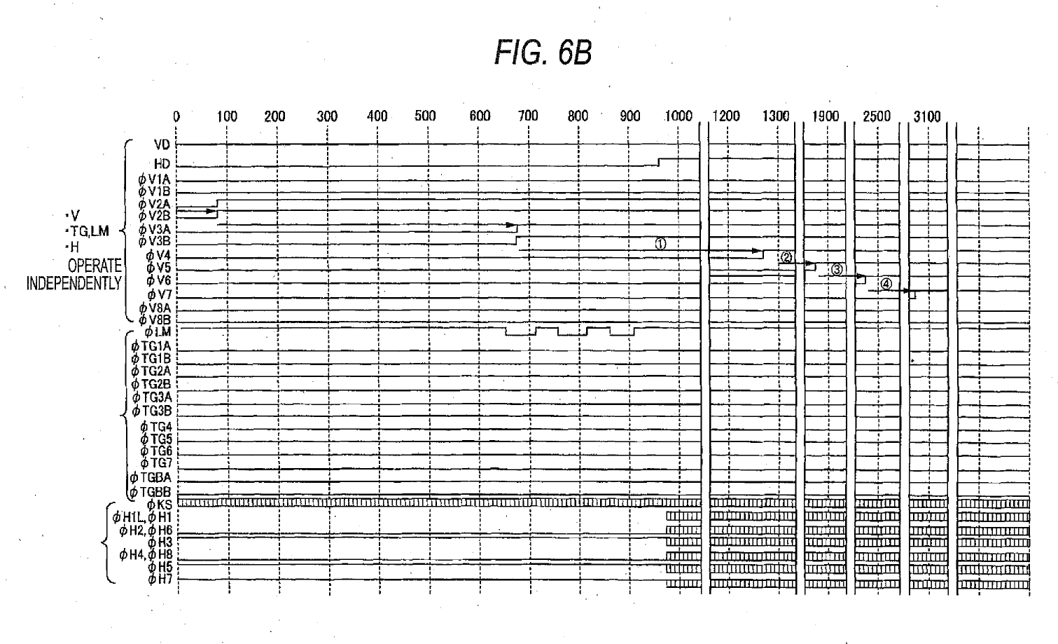

FIGS. 6A and 6B are an enlarged view of Pattern 1 shown in FIG. 5. In Pattern 1, timings at which the transfer pulses φV2, φV3, . . . , and φV7 are applied to the vertical transfer electrodes V2, V3, . . . , and V7 are shifted from one another. The transfer pulses are designed such that the transfer pulse φV2 rises after waiting time “76” (counted by the number of clock pulses of the master clock, the same will being applied hereinafter) has elapsed from start timing 0. The transfer pulse φV3 rises when waiting time “600” has elapsed with respect to the transfer pulse φV2. Thereafter, the transfer pulses φV4, φV5, φV6, and φV7 rise sequentially after waiting time “600” has elapsed.

In order to design these pulses, as shown in the left portion of FIG. 6A, a command for designating a status memory start address is written at an address “0x000” of the clock memory 46, a command for designating the clock waiting time “76” is written at an address “0x001” of the clock memory 46, and a command for designating the clock waiting time “600” is written at the next address “0x002” of the clock memory 46.

The clock waiting time “600” for the initial transfer pulse φV3 is repeated four times for the transfer pulses φV4, φV5, φV6, and φV7. When the clock waiting time is sequentially written at the subsequent addresses of the clock memory 46, the storage capacity for the command data is increased.

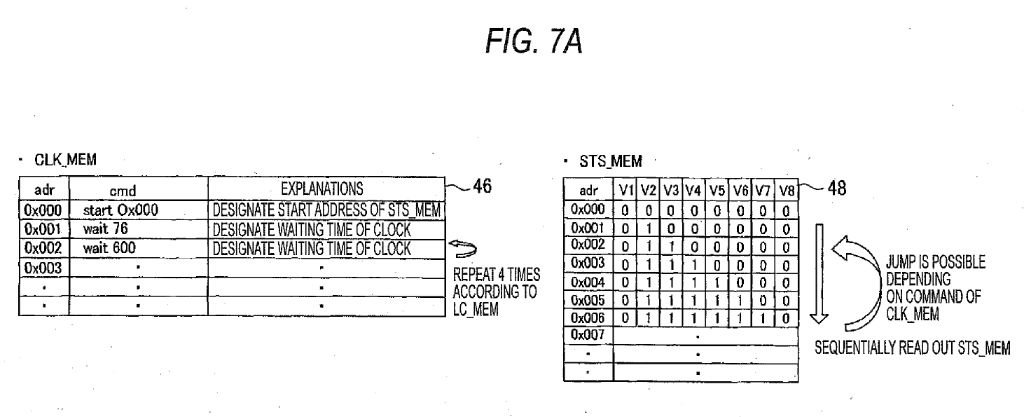

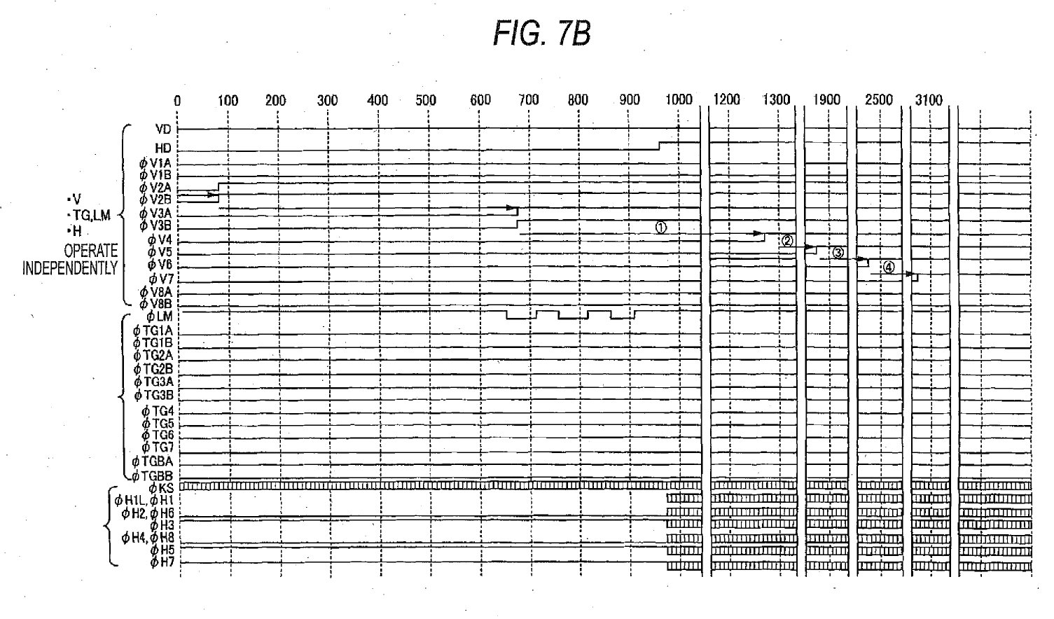

In this embodiment, therefore, as shown in the right portion of FIG. 6A, a command for designating the operation to repeat a command at an address “0x002” of the clock memory 46 four times is written at an address “0x000” of the loop control memory 47. As a result, the command of the waiting time “600” is repeated four times, and the respective pulse waveforms are generated as described with reference to FIGS. 7A and 7B.

FIGS. 7A and 7B are a timing chart illustrating the relationship between the clock memory 46 and the status memory 48. In the status memory 48, status data for setting all of the electrodes V1, V2, . . . , and V8 to the level or “1” is stored at an address “0x000”. Status data for setting only the electrode V2 to the level “1” is stored at an address “0x001”, and status data for setting the electrodes V2 and V3 to the level “1” is stored at an address “0x002”. Status data for setting the electrodes V2, V3, and V4 to the level “1” is stored at an address “0x003”, . . . , and status data for setting the electrodes V2, V3, V4, V5, V6, and V7 to the level “1” is stored at an address “0x006”.

The operation to read out data from the status memory 48 storing the status data is performed in the sequence of addresses. The timing of the data reading operation is adjusted according to the command data (the wait command, the loop command), which are stored in the second memory section 45.

If the command at the address “0x000” of the clock memory 46 is executed, first, the status memory start address is designated. In the illustrated example, the status memory start address “0x000” is designated, and hence the potentials of all of the electrodes V1, V2, . . . , and V8 are set to the level “0”.

The command at the next address “0x001” of the clock memory 46 designates the waiting time “76”. Therefore, the status data at the next address “0x001” of the status memory 48 is read out after the waiting time “76” has elapsed. As a result, the potential of the electrode V2 rises to the level 1 after the waiting time “76” has elapsed from the start timing.

The status data at the next address “0x002” of the status memory 48 is data for setting the electrodes V2 and V3 to the level “1”. This status data is read out according to the command at the next address “0x002” of the clock memory 46, that is, after the waiting time “600” has elapsed. Therefore, the potential of the electrode V3 rises to the level “1” when the waiting time “600” has elapsed after the potential of the electrode V2 had risen to the level The command for designating the waiting time “600” at the address “0x002” of the clock memory 46 is designated, by the loop control memory 47, to be repeated four times (FIG. 6A). Therefore, the status data at the next address “0x003” of the status memory 48 is read out after the waiting time “600” has elapsed, the status data at the next address “0x004” of the status memory 48 is read out when the waiting time “600” has further elapsed, . . . , and the status data at the address “0x006” of the status memory 48 is read out when the waiting time “600” has elapsed after the status data at the address “0x005” of the status memory 48 had been read out.

When the execution of the four loops designated at the address “0x000” of the loop control memory 47 ends, the operation for one horizontal transfer period caused by the command at the address “0x002” of the clock memory 46 ends.

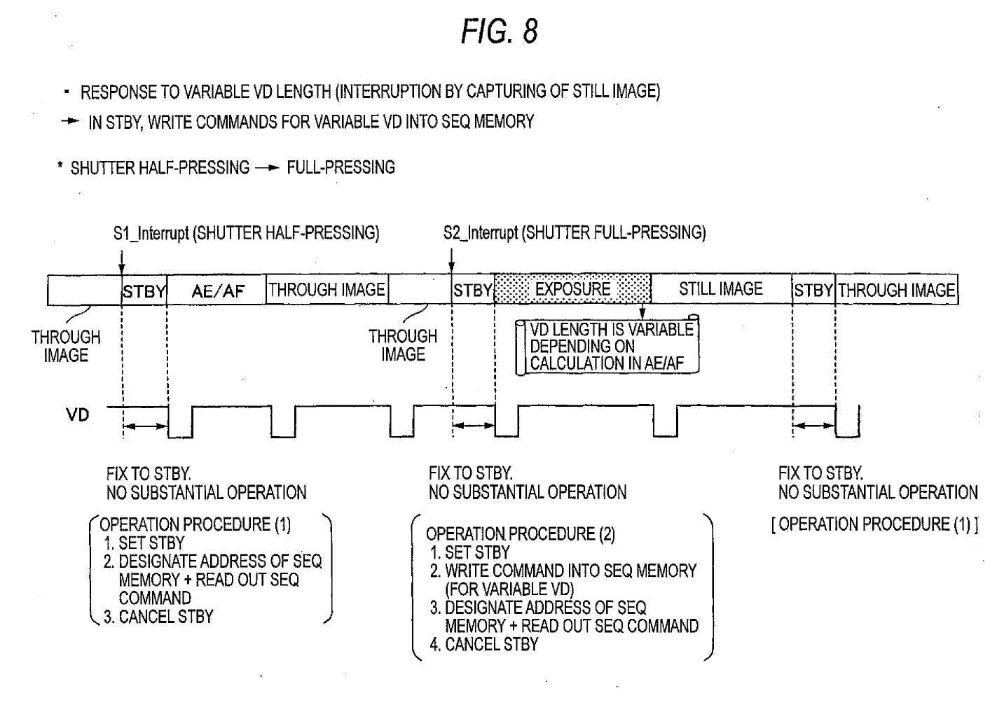

FIG. 8 is a timing chart in a case where the digital camera captures a still image. In a state where the digital camera is powered on, image data output from the solid-state imaging device is displayed as a through image on a liquid crystal display unit provided on the rear surface of the digital camera. When a user half-presses a shutter button (a switch S1 is turned on), processing for calculating automatic exposure (AE) and automatic focusing (AF) is performed after a predetermined standby (STBY) time has elapsed, and then the through image is displayed.

When the user next fully presses the shutter button (a switch S2 is turned on), “exposure” is performed after the predetermined standby (STBY) time has elapsed, and an operation to read out a captured image from the solid-state imaging device is performed subsequently.

The time for “exposure” is variable depending on the calculation result of immediately preceding AE and AF, and the required number of driving pulses for the solid-state imaging device is also variable. Therefore, the digital camera of this embodiment is configured such that, during the standby mode after the switch S2 is turned on, the sequence memory is accessed and the loop number for the required pattern waveform to be written into the sequence memory is increased or decreased depending on the exposure time. With this configuration where the data stored in the sequence memory is overwritten during the operation of the digital camera, even though an unexpected driving mode is required, it is possible to avoid a situation of running short of the memory capacity.

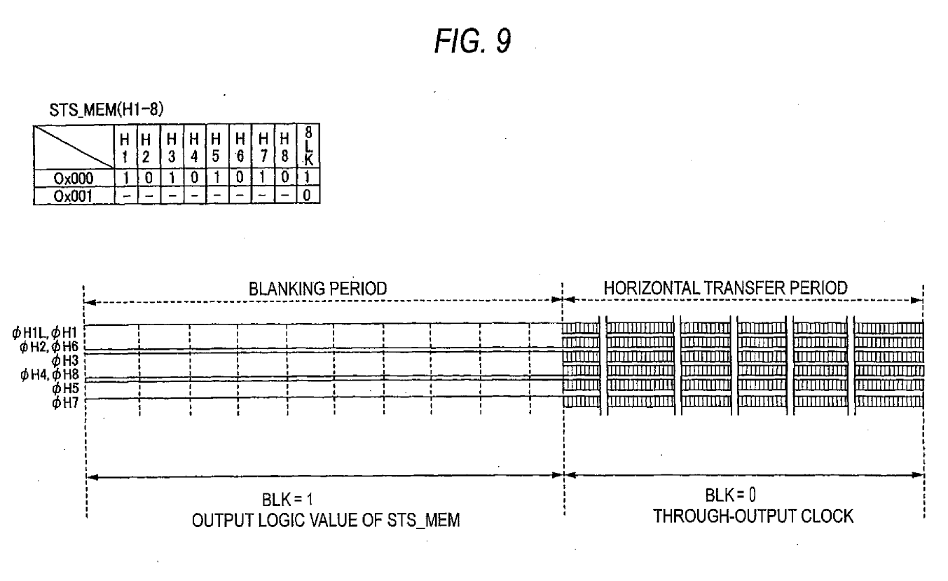

FIG. 9 is a diagram illustrating the configuration of the status memory for the horizontal transfer pulses φH1 to φH8 and pulse control. The horizontal transfer pulses function as the clock output during the horizontal transfer. If the clock logic values are actually written into the status memory, the amount of stored data is excessively large.

In this embodiment, therefore, a BLK portion is provided in the status memory for the horizontal transfer pulses as shown in the upper left portion of FIG. 9. Then, “0” is written into the BLK portion at an address “0x001” indicating the horizontal transfer, and “1” is written into the BLK portion at an address “0x000” indicating the blanking.

With this configuration, during the blanking period, the status data at the address “0x000” of the status memory is output. Also, during the horizontal transfer period, the master clock supplied from the AFE circuit 12 (in this embodiment, the master clock is generated by the AFE circuit, but alternatively, the master clock may be generated by the timing generator and then supplied to other circuits) is through-output as the horizontal transfer pulse as it is. With this configuration, it is not necessary to store clock data in the status memory, and as a result, the memory capacity can be reduced.

As described above, the digital camera of this embodiment is configured such that data for designating operations for one operation mode (operations during a period from a vertical synchronization pulse VD to the next vertical synchronization pulse VD) is stored in the sequence memory 42 and the loop pointer memory 43 in units of the horizontal transfers. The operations for one horizontal transfer are stored in the clock memory 46 in units of the clocks. A loop command corresponding to the horizontal transfer periods is stored in the loop control memory 47. Transitions of logic values are stored in the status memory 48. The sequencer section 40 having the memories 42, 43, 46, 47, and 48 starts a sequence operation from the start address designated in the serial register 31. Therefore, various and complicated driving pulses can be generated by the data stored in the memories having a small capacity.

In this embodiment, since the memories 51, 52, and 53 are provided in the sequencer section 40, the period length of the horizontal transfer period can be variably set for each horizontal transfer period. Therefore, frame rates can be easily changed.

The timing generator 14 of this embodiment performs data communication by serial communication. In a case where the access bits of the serial communication are not restricted, the sequence memory 42 and the loop pointer memory 43 may be constituted of the same memory. Therefore, the memory size can be further reduced.

In this embodiment, the clock command and the loop command which are stored in the second memory section 45 are stored in different memories 46 and 47, and separately read out therefrom. Therefore, the loop determination can be performed without time delay or simultaneously with the clock command. As a result, the read-out timing is not restricted due to the loop determination, and it is possible to cope with the wait command for each clock.

In this embodiment an address of the clock memory at which a loop is required is designated by the loop command of the loop control memory 47. Therefore, it is possible to cope with a multi-stage loop or a nested loop without increasing the memories. When the chip size and the disposition of a multi-stage counter are not restricted, any number of multi-stage loops can be incorporated.

In this case, as a method of indicating the end of a loop during one horizontal transfer period, one of the following methods may be used:

(a) a loop of fixed stages is used;

(b) a control register for designating the number of loop stages is provided, and a variable-stage loop by the setting of the registers is used; and

(c) an end bit is provided in a loop command in the loop control memory, and a variable-stage loop by the setting of the commands is used.

In this embodiment, command data are used as data to be stored in the memories, and a loop command is effectively use to realize a multi-stage loop. Therefore, the capacity of the memories for storing the command data can be reduced. Also, the status memory 48 is configured such that address call is performed by the call command. Therefore, the data capacity of the status data can also be reduced, and the size of the memory chip can be further reduced.

In this embodiment, one operation mode is partitioned in units of the horizontal transfer period, and one horizontal transfer period is partitioned in units of the clock. Therefore, the combination can be easily changed, and the flexibility of the pulse generation can be enhanced.

Alternatively, the loop pointer memory 43 and the loop control memory 47 may not be used, and the loop command may be incorporated into the clock memory. In the alternative, however, it is required that the loop command in the clock memory is once determined and then the instruction at the loop destination is read. In the read-out timing, therefore, one clock for the loop determination, and one clock for reading out an instruction at a loop destination, or two clocks in total are restricted. In a system in which such restriction is allowable, the memory capacity can be further reduced.

In the solid-state imaging device driving apparatus of the invention, various driving pulses of an imaging device can be generated with a small memory capacity. Therefore, the apparatus is useful in application to a digital camera in which functions are to be increased, or the like.

What is claimed is:

1. A solid-state imaging device driving apparatus for generating a driving pulse for a solid-state imaging device, the apparatus comprising:
a horizontal synchronization-related memory that stores period length data being set for each of horizontal synchronization periods, the horizontal synchronization-related memory being accessed every horizontal synchronization signal;
a status memory that is accessed at the same timing as the horizontal synchronization-related memory is accessed, and stores status data at each address as a logic value; and
a command data memory that is accessed at the same timing as the horizontal synchronization-related memory is accessed, and stores command data sequentially, wherein
the driving pulse is generated by reading the status data from the address, which is designated by each command data, of the status memory.

2. The apparatus according to claim 1, wherein
the horizontal synchronization-related memory stores, in addition to the period length data, toggle position data of the horizontal synchronization signal being set in units of the horizontal synchronization period, toggle position data of a signal representing an image data output period, and toggle position data of a signal representing a black level output period, and
the respective toggle position data are accessed every horizontal synchronization signal.

3. The apparatus according to claim 1, further comprising:
a control section including a serial register that receives and stores plural pieces of setting data; and
a sequencer section that operates with using an output of the serial register as address data and generates the driving pulses by sequence control, wherein
the control section and the sequencer section are provided independently, and
the status memory, the command data memory and the horizontal synchronization-related memory are provided in the sequencer section.

4. The apparatus according to claim 2, further comprising:
a control section including a serial register that receives and stores plural pieces of setting data; and
a sequencer section that operates with using an output of the serial register as address data and generates the driving pulses by sequence control, wherein
the control section and the sequencer section are provided independently, and
the status memory, the command data memory and the horizontal synchronization-related memory are provided in the sequencer section.

5. The apparatus according to claim 3, wherein
the solid-state imaging device includes a CCD-type solid-state imaging device having vertical charge transfer paths and a horizontal charge transfer path, and
the command data memory includes
a first memory section that stores command data for a plurality of horizontal synchronization periods constituting one operation period in units of the horizontal synchronization period, and
a second memory section that stores command data for each horizontal synchronization period in units of a clock.

6. The apparatus according to claim 4, wherein
the solid-state imaging device includes a CCD-type solid-state imaging device having vertical charge transfer paths and a horizontal charge transfer path, and
the command data memory includes
a first memory section that stores command data for a plurality of horizontal synchronization periods constituting one operation period in units of the horizontal synchronization period, and
a second memory section that stores command data for each horizontal synchronization period in units of a clock.

7. The apparatus according to claim 5, wherein
the second memory section includes
a clock memory that stores command data for designating different clock waiting times at different addresses, and
a loop control memory that stores command data for designating number of times a clock waiting time at a designated address among the addresses is repeated.

8. The apparatus according to claim 6, wherein
the second memory section includes
a clock memory that stores command data for designating different clock waiting times at different addresses, and
a loop control memory that stores command data for designating number of times a clock waiting time at a designated address among the addresses is repeated.

9. The apparatus according to claim 7, wherein
the first memory section includes
a sequence memory that stores command data for designating a read address of the clock memory, and
a loop pointer memory that stores commend data for, at the same timing as the command data stored in the sequence memory designates, designating a read address of the loop control memory.

10. The apparatus according to claim 8, wherein
the first memory section includes
a sequence memory that stores command data for designating a read address of the clock memory, and
a loop pointer memory that stores commend data for, at the same timing as the command data stored in the sequence memory designates, designating a read address of the loop control memory.

11. The apparatus according to claim 7, wherein each of the status memory, the clock memory, and the loop control memory is configured to be partitioned into three groups of a first group for a vertical transfer pulse, a second group for a transfer gate pulse, and a third group for a horizontal transfer pulse.

12. The apparatus according to claim 8, wherein each of the status memory, the clock memory, and the loop control memory is configured to be partitioned into three groups of a first group for a vertical transfer pulse, a second group for a transfer gate pulse, and a third group for a horizontal transfer pulse.

13. The apparatus according to claim 9, wherein each of the status memory, the clock memory, and the loop control memory is configured to be partitioned into three groups of a first group for a vertical transfer pulse, a second group for a transfer gate pulse, and a third group for a horizontal transfer pulse.

14. The apparatus according to claim 10, wherein each of the status memory, the clock memory, and the loop control memory is configured to be partitioned into three groups of a first group for a vertical transfer pulse, a second group for a transfer gate pulse, and a third group for a horizontal transfer pulse.

15. The apparatus according to claim 5, wherein when the one operation period is changed, the change of the one operation period is dealt with by variably controlling the number of repeated loops stored in the first memory section or the second memory section.

16. The apparatus according to claim 6, wherein when the one operation period is changed, the change of the one operation period is dealt with by variably controlling the number of repeated loops stored in the first memory section or the second memory section.

17. The apparatus according to claim 1, wherein when a same clock signal as a master clock is used as the driving pulse, the status memory stores data for designating through output of the master clock as the driving pulse in place of storing the status data of the driving pulse.

18. An imaging apparatus comprising:
a solid-state imaging device; and
the solid-state imaging device driving apparatus according to claim 1, for driving the solid-state imaging device.
